(19) United States
(12) Patent Application Publication
(10) Pub. No.: US 2023/0207514 A1
(43) Pub. Date: Jun. 29, 2023

(54) APPARATUSES AND METHODS FOR DIE BOND CONTROL

(71) Applicant: ADEIA SEMICONDUCTOR BONDING TECHNOLOGIES INC., San Jose, CA (US)

(72) Inventors: Guilian Gao, San Jose, CA (US); Gaius Gillman Fountain, JR., Youngsville, NC (US); Cyprian Emeka Uzoh, San Jose, CA (US); Thomas Workman, San Jose, CA (US)

(21) Appl. No.: 18/069,783

(22) Filed: Dec. 21, 2022

Related U.S. Application Data
(60) Provisional application No. 63/293,313, filed on Dec. 23, 2021.

(51) Int. Cl. H01L 23/00; H01L 21/67; H01L 21/683

(52) U.S. Cl. CPC H01L 24/80; H01L 21/67144; H01L 21/6838; H01L 21/6831; H01L 24/74; H01L 2224/80895; H01L 2224/80896; H01L 2224/74

(57) ABSTRACT

A system for direct bonding can include a substrate support configured to hold a substrate for direct bonding and a die handling tool including an end effector configured to hold a die and bring the die into contact with the substrate supported on the substrate support, the end effector configured to initiate contact between the substrate and a bond initiation region of the die and to subsequently allow contact between the substrate and other regions of the die.

### CROSS REFERENCE TO RELATED APPLICATIONS

This application claims benefit of priority to U.S. Provisional Patent Application No. 63/293,313, filed Dec. 23, 2021, titled “APPARATUSES AND METHODS FOR DIE BOND CONTROL,” the contents of which are hereby incorporated by reference in their entirety.

### BACKGROUND

### Field

The field relates to apparatuses and methods for die bond control.

### Description of the Related Art

Semiconductor elements, such as semiconductor wafers or integrated device dies, can be stacked and directly bonded to one another without an adhesive. For example, nonconductive (dielectric or semiconductor) surfaces can be made extremely smooth and treated to enhance direct, covalent bonding, even at room temperature and without application of pressure beyond contact. In some hybrid direct bonded structures, nonconductive field regions of the elements can be directly bonded to one another, and corresponding conductive contact structures can be directly bonded to one another. In some cases, voids may exist along the bond interface between opposing semiconductor elements. Accordingly, there remains a continuing need for improved bonding methods that reduce voids in bonded structures.

### BRIEF DESCRIPTION OF THE DRAWINGS

The detailed description is set forth with reference to the accompanying figures. The use of the same numbers in different figures indicates similar or identical items

For this discussion, the devices and systems illustrated in the figures are shown as having a multiplicity of components. Various implementations of devices and/or systems, as described herein, may include fewer components and remain within the scope of the disclosure. Alternatively, other implementations of devices and/or systems may include additional components, or various combinations of the described components, and remain within the scope of the disclosure

FIGS. 1A-1B illustrate a bonding tool for bonding a singulated integrated device die.

FIGS. 1C-1G illustrate graphs and figures showing die defects caused by the bonding tools as illustrated in FIGS. 1A-1B.

FIGS. 2A-2D illustrates a step-by-step process using single point initiation to achieve void-free bonding.

FIG. 2E illustrates a graph showing bond initiation force as a function of the time to initiate the bonding.

FIG. 3A illustrates a schematic diagram of a bonding tool, according to an embodiment.

FIG. 3B illustrates a schematic diagram of a bonding tool according to another embodiment

FIG. 4 illustrates a schematic diagram of a bonding tool according to another embodiment.

FIGS. 5A-5D illustrate schematic diagrams of various embodiments of another bonding tool.

FIGS. 5E-5I illustrate top views of various embodiments of an end effector.

FIGS. 5J-5K illustrate schematic side sections of various embodiments of an end effector.

FIGS. 5L-5O illustrate schematic diagrams of various embodiments of a bonding tool.

FIGS. 6A-6E illustrate a bonding tool according to another embodiment.

FIGS. 7A-7E illustrate a bonding tool according to another embodiment.

FIG. 8 illustrates a bonding tool according to another embodiment.

FIG. 9 illustrates a bonding tool according to another embodiment.

FIG. 10A is a schematic diagram of a bonding tool according to another embodiment.

FIG. 10B is a chart illustrating bond wave speed for various conditions.

FIG. 11 is a schematic view of another embodiment of a bonding tool.

### DETAILED DESCRIPTION

Various embodiments disclosed herein relate to improved bonding methods and bonding tools for directly bonding two elements (e.g., two semiconductor elements). Bonding tools used for die-to-wafer (D2W) and die-to-die (D2D) bonding typically use a vacuum force to pick up the die and to keep the die in place during die transportation and/or bonding. An uneven vacuum force on the die surface causes the bonding surface to deform, which is especially problematic for thin dies. For example, in some embodiments, the die to be bonded may comprise a thinned substrate or integrated device die having a thickness in a range of about 10 μm to 500 μm, in a range of about 30 μm to 500 μm, in a range of about 50 μm to 500 μm, or in a range of about 10 μm up to 800 μm, or up to 1000 μm. Undesirable deformation of the die may cause interruption of bond front propagation which can lead to bonding voids that inhibit electrical connection between the die and the substrate. Also, as a result of the defect on the vacuum pick up bonding tool, more than one portion of the die bonding surface may contact the host surface simultaneously during the bonding step. The multiple contacting portions can generate their own propagating wave front. The competing opposing propagating wave fronts may tend to merge with occluded void(s) in the bonded structure. Methods and apparatuses described herein can improve control over the bonding process to reduce such voids. For example, methods and apparatuses can facilitate control over direct bond propagation front(s) to minimize or eliminate void formation at a direct bond interface between a die and a substrate, which can be, for example, a second die, a wafer or a carrier of another type.

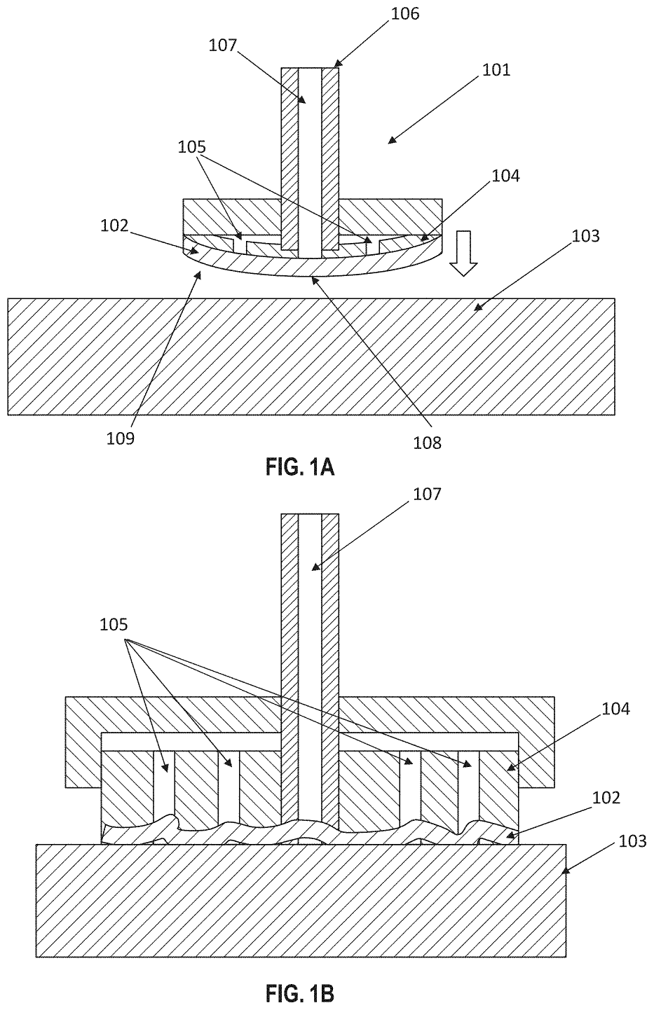

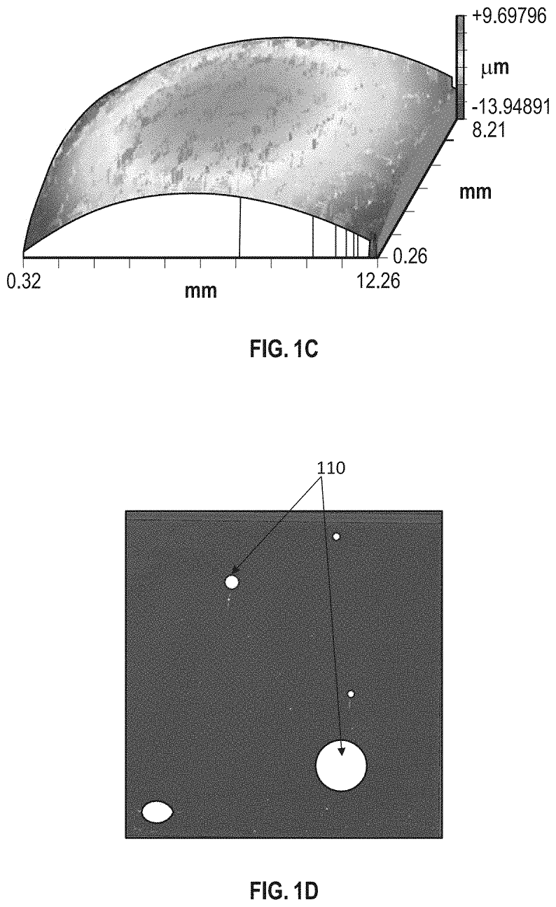

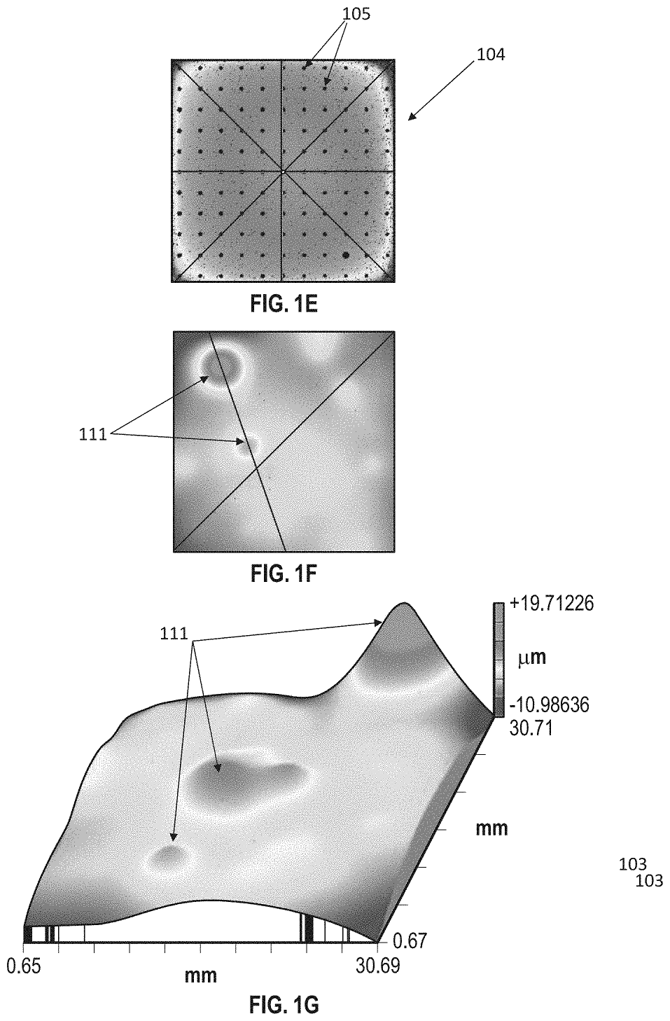

FIG. 1A illustrates a bonding tool 101 for bonding a singulated integrated device die 102 (which can include active circuitry including one or more transistors (not shown) and/or passive circuitry) to a substrate 103 (such as a host wafer). The bonding tool 101 can comprise a plate 104 with a single vacuum hole or a matrix of multiple vacuum holes 105 or channels connected to a shaft 106 (also referred to as a shank) having a central vacuum channel 107. The vacuum holes 105 can be connected to the central vacuum channel 107 by one or more transverse passages (not shown). As shown, the plate surface 104 can be curved to facilitate center-first contact. The bonding tool 101 of FIG. 1A can use a vacuum force during die transport, alignment and positioning, with the vacuum force applied to the center of the die 108, as well as to peripheral regions of the die 109 through the vacuum hole(s) 105. To bond the die 102 to the substrate 103 (e.g., a wafer), the shaft 106 is translated downward towards the substrate surface. A sensor (not shown) on the shaft 106 measures the resistance force encountered. The shaft 106 continues to translate downwards until a pre-set or predetermined force is reached (bond initiation). The vacuum is released to allow the bonding wave to propagate across the bond interface between the die 102 and substrate 103.

In various arrangements, a control system (not shown) can provide a controllable delay between applying the bond initiation force and releasing vacuum, and a controllable delay between releasing the vacuum and moving the shaft 106 upwards. The center vacuum channel 107 can be switched between applying a vacuum and a pressurized gas. However, even though the bonding tool 101 may be shaped to cause the center of the die 102 to contact the substrate 103, applying the vacuum force to the center of the die 102 as well as to peripheral regions of the die 102 during bonding can cause multi-point bond initiation as opposed to a single point or single region bond initiation.

For example, as shown in FIG. 1B, the vacuum force in conventional die bonding tools scan cause deformation of the thin die (e.g., puckering), which can be caused by multiple point bonding initiation due to die deformation. Bonding device dies is challenging as the die 102 may be warped or have an uneven surface, as shown in FIG. 1C. Continued application of the vacuum on both central and peripheral regions (in combination with upward support pressure applied from the substrate 103 after bonding initiation can cause bonding to occur at lower areas of the die 102 while higher areas of the die 102 continue to be pulled upwardly by the vacuum force, resulting in the puckering effect shown in FIG. 1B. The die 102 is accordingly held down with a downward force applied by the plate 104 of the bonding tool 101 and simultaneously pulled upwardly by a vacuum force applied through the central vacuum channel 107 and the vacuum holes 105, which can cause puckering. Upon contact to the hosting substrate 103, the puckering may induce multiple portions of the die 102 to contact the substrate 103 simultaneously. The multiple contacting portions of the die 102 on the substrate 103 can generate competing propagating bonding waves. The convolution of the competing propagating waves can occlude or trap air or voids in the directly bonded die 102 to substrate 103. For example, the die surface in regions already bonded to the substrate 103 do not have freedom to relax and release the trapped voids. When the vacuum is released, the die 102 tends to return to its natural shape, which can cause the edge of the substrate 103 to contact the substrate 103 early in the bonding process, causing air to be trapped between the die 102 and the substrate 103 103. The trapped air can result in voids 110 along the bond interface between the die 102 and substrate 103 as shown in FIG. 1D. The issues shown described with respect to FIGS. 1B-1D are particularly exacerbated for thinned dies, and even more so for larger dies.

As explained above, although the die bonding tool 101 of FIG. 1A may be curved so as to cause center contact between the die 102 and the substrate 103, the actual surface topology of the bonding tool 101 is inadequately structured to control the bonding process to avoid the problems discussed above. For example, FIG. 1E illustrates a surface profile of a plate 104 of a bonding tool with an array of vacuum holes 105. In FIG. 1E, the center of the plate 104 is about 10 microns above the edges and about 30 microns above the corner regions of the plate 104. When used for direct bonding a die to a substrate, as shown in FIGS. 1F-1G, the bonding tool that includes a plate with a central vacuum channel and peripheral vacuum holes similar to that shown in FIG. 1A can induce multi-point bond initiation, with multiple bond fronts propagating from those multiple points of contact 111, which can leave voids in regions between the multiple contact points 111.

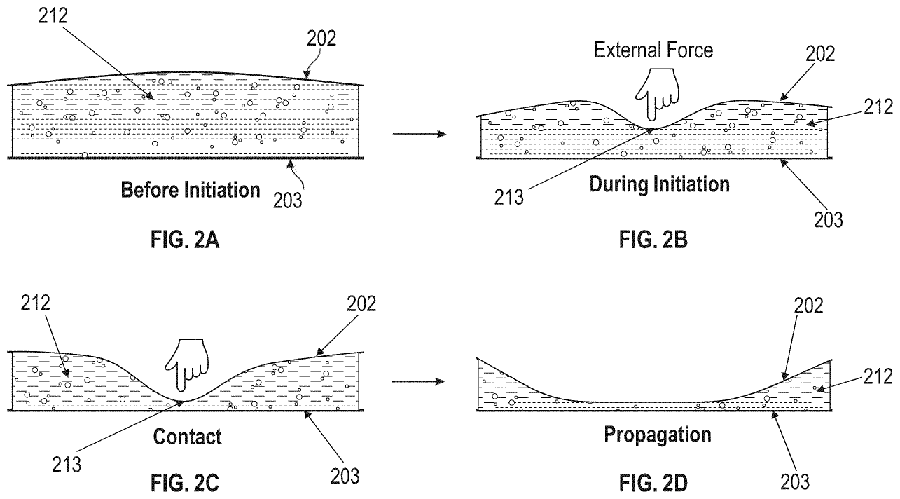

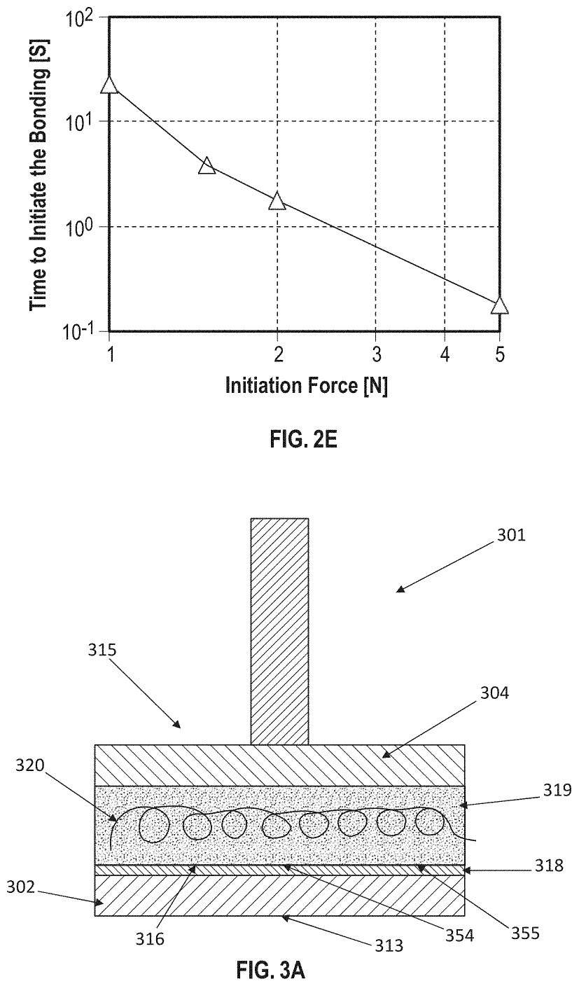

FIGS. 2A-2E illustrate an overview of various methods disclosed herein for reducing or eliminating voids along a bond interface between two bonded elements in a bonded structure. As explained above, in die-to-wafer (D2W) or die-to-die (D2D) bonding processes, warpage of the die(s) can cause voids when used with conventional bonding tools. Thinned and/or large dies are particularly susceptible to such warpage. Beneficially, various embodiments disclosed herein can be used in D2W and D2D bonding techniques to reduce or eliminate voids in the bonded structure due to uncontrolled bond front propagation.

As shown in FIG. 2A, when a semiconductor element (such as a die 202) is placed on top of an activated substrate 203 (e.g., a host wafer or host die) for example, a thin air layer 212 separates the die 202 from the substrate 203, such that the die 202 is floating or can slide over the host substrate 203. In FIG. 2B, an external force (which can be applied by an end effector of a robotic tool) can be used to initiate the bonding by forcing out the air between the die 202 and the substrate 203 in the vicinity of the contact. In FIG. 2B, the external force can be applied to initiate contact between the substrate 203 and a bond initiation region 213 of the die 202 and to subsequently allow contact between the substrate 203 and other regions of the die 202. The process is controlled such that the bond initiation region 213 is a single “point” of contact, rather than multiple separated regions. In the example of FIG. 2B, the external force can be applied to cause contact between a central bond initiation region 213 of the die 202 and the substrate 203, but in other embodiments, the external force can be applied to cause contact between the substrate 203 and a peripheral bond initiation region at an edge of the die 202. In some embodiments (for example, in embodiments using a rectangular or square die), the bond initiation region 210 can comprise a central spine of a long axis of the die, and the other regions can include regions on opposite regions of the die 202. Once the die 202 and substrate 203 make contact as shown in FIG. 2C, the bonding spontaneously propagates the bonding region across the interface between the die 202 and substrate 203, as shown in FIG. 2D. Advantageously, in the disclosed embodiments, single point bond initiation can be achieved such that bond wave propagation from the center of the die 202 or from one edge of the die 202 to another, which can achieve void-free direct bonding.

As shown in FIG. 2E, the time to initiate the bonding depends on the initiation force. The time to initiate bonding can be lower for higher initiation forces, and higher for lower initiation forces. The initiation forces generally are imparted at the point or localized region at which the die 202 makes contact with the substrate 203 (e.g., at a central region of the die or at an edge of the die) and not across the whole die 202. The initiation force can be applied to initiate contact, after which the bond propagates without externally applied pressure and at room temperature.

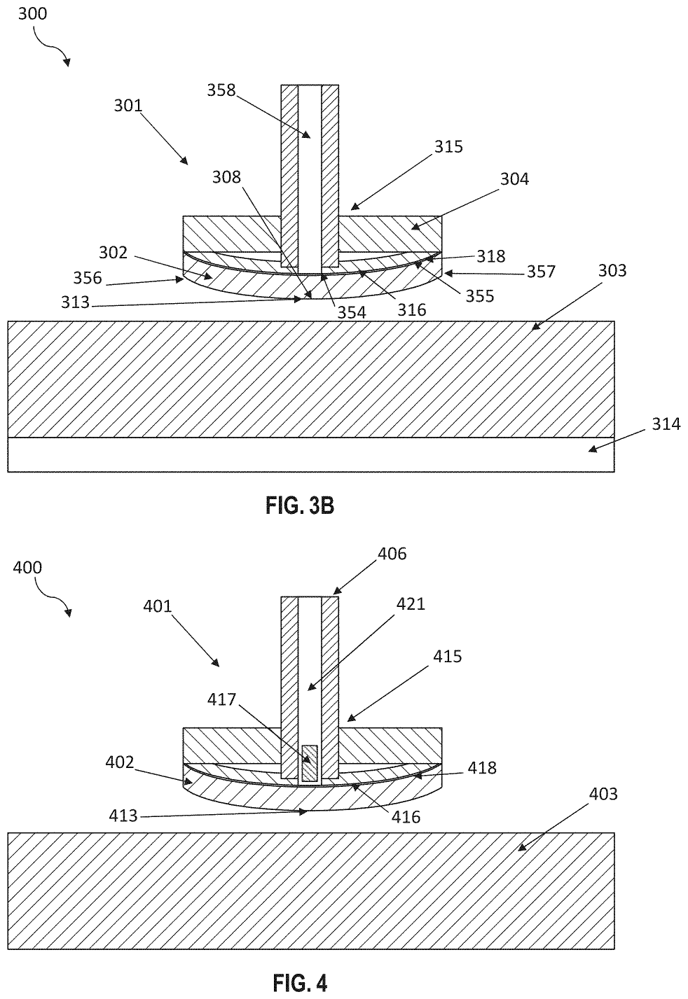

Accordingly, various embodiments disclosed herein (for example as seen in FIGS. 3A and 3B) can include a system 300 for direct bonding that includes a substrate support 314 configured to hold a substrate 303 for direct bonding, and a bonding tool 101 (also referred to as a die handling tool) including an end effector 315 (also referred to herein as a pick head or bond head) configured to hold a die 302 and bring the die 302 into contact with the substrate 303 supported on the substrate support 314. The end effector 315 can be configured to initiate contact between the substrate 303 and a single bond initiation region 313 of the die 302 and to subsequently allow contact between the substrate 303 and other regions of the die. In various embodiments, the end effector 315 is configured to support any die having a determined geometrical profile, for example a rectangular die, a square die, or a polygonal die, and, in some embodiments, a circular die. As explained herein, the end effector 315 can be configured to support a thinned die having a thickness of, less than about 1000 μm, less than 800 μm, less than about 500 μm, or less than 100 μm, for example, less than 30 μm or less than 10 μm. For example, the end effector 315 can have a curved die support surface 316, and the die 302 can conform to the curvature of the die support surface 316. For example, the die support surface 316 can be curved such that a central region 354 of the die support surface 316 protrudes relative to peripheral regions 355 of the die support surface 316. The central region 354 can be configured to support the bond initiation region 313 of the die 302. In other embodiments, the die support surface 316 can be shaped such that a side edge 356 of the die 302 protrudes relative to the opposing side 357 and the central region 308 such that the side edge 356 makes initial contact with the substrate 303, and bonding propagates from the side 356 to the opposite side 357. In some embodiments, the die support surface 316 can be flat, and an actuator (for example, an actuator as shown in FIG. 4) can be used to impart contact between the die 302 and the host substrate 303. In some embodiments, the end effector 315 can comprise the die support surface 316 and an actuator (e.g., a release actuator). The actuator can be configured to separate the bond initiation region 313 of the die 302 from the die support surface 312 prior to separating other regions of the die 302.

In some embodiments disclosed herein, the bonding tool 301 can be configured to bond the die 302 to the substrate 303 without heating and without pressure beyond bringing the die 302 and substrate 303 into contact. The force or pressure can be limited to the bond initiation region 313, such as by curvature, robotics control and/or an actuator, and pressure may not be applied across the entire die 302. In some embodiments, the initial force or pressure may be applied to the bond initiation region 313, after which an additional momentary pressure may be applied to a portion of or across the entire die 302 from the backside surface. In some embodiments, the die handling tool 301 can include a height or proximity position sensor (not shown) and a control circuit (not shown) configured to halt downward movement of the end effector 315 prior to contact with the substrate 303 and subsequently initiating contact between the bond initiation region 313 of the die 302 and the substrate 303. In some embodiments, the die handling tool can include a resistance force sensor (not shown) to limit downward force.

FIGS. 3A-3B illustrate example embodiments of die bonding tools 301 that utilize capillary forces to support a die 302 for direct bonding. For example, the bonding tool 301 can include an end effector 315 that releasably secures the die 302 to the die handling tool through capillary action of a layer of liquid 318 provided between a die support surface 316 of the end effector 315 and the die 302. In FIG. 3A, for example, the end effector 315 can include a plate 304 and porous media 319 coupled to the plate 304, with the porous media 315 comprising or at least partially defining the die support surface 316. In FIG. 3A, the porous media 319 can comprise a porous ceramic material that includes or at least partially defines the die support surface 316. An amount of liquid (e.g., water) can be dispensed or dipped onto the die support surface to form a thin, continuous layer 318 to hold the die 302 in place during transportation and/or bonding. The end effector 315 can comprise a release mechanism comprising a heater 320 configured to evaporate at least a portion of the layer of liquid 318 for releasing the die. As shown, the heater 320 can be embedded in the porous media 315 (e.g., which can comprise a ceramic material). Once the die 302 is aligned and placed on the substrate 303, the heater 316 can be activated or pulsed to evaporate the liquid 318 and release the die 302 without uncontrolled deformation. While illustrated as planar, the bond head 315 can be curved and/or include a bond initiation actuator as described elsewhere herein.

Beneficially, in FIG. 3A, the thin liquid layer 318 can support the die 302 using surface tension of the liquid 318. The liquid 318 can conform to the shape of the bonding tool 301 (e.g., the shape of the die support surface 316) obviate the effect of small surface irregularities in the bonding tool 301. In some embodiments, the heater 320 can be activated to uniformly evaporate the liquid 318. In other embodiments, the heater 320 can be controlled so as to evaporate the liquid 318 in a manner that controls the sequence of release from the single-point contact to other regions of the die 302 in a manner to minimize or eliminate voids. For example, the heater 320 can be activated to evaporate liquid 318 from the center outwardly, or, alternatively, from one side edge to an opposing side edge to enable single-region or single-point bond initiation at the bond initiation region 313. As an example, a heater 320 may evaporate a liquid layer 318 having a thickness of less than 100 nm, less than 10 nm, or less than 1 nm. In some embodiments, the liquid layer may be approximately 1 nm in thickness. The energy needed to evaporate the liquid layer may be less than 100 J, less than 10 J, or less than 1 J. In some embodiments the energy needed to evaporate the liquid layer may be about 0.26 J. the time taken to evaporate the liquid layer may be less than 100 seconds, less than 10 seconds, or less than 1 second. In some embodiments, the time taken to evaporate the liquid layer may be about 0.26 seconds. It should be appreciated that the porous media 319 can comprise a curved surface. In some embodiments, the curved surface can be curved such that a central region 354 of the die support surface 316 protrudes relative to peripheral regions 355 of the die support surface 312.

In FIG. 3B, the end effector 315 can comprise a smooth, non-porous or solid plate 304 having a liquid dispensing port 358. The die support surface 316 can be curved to induce controlled bonding initiation. In FIG. 3B, as with FIG. 3A, liquid (e.g., water) can be dispensed or dipped onto the die support surface 316 to form a thin, continuous layer 318 to hold the die 302 in place during transportation and/or bonding. For example, in FIG. 3B, the end effector 315 can comprise a liquid dispensing port 358 to supply the liquid 318 between the die support surface 316 and the die 302. Instead of, or in addition to, evaporating the liquid 318, a vacuum force can be applied to evacuate the liquid away from the die support surface 316 to release the die 302. In some embodiments, for example, the vacuum force can be applied through the liquid dispensing port 358. In some embodiments, a venturi device (not shown) or opening a valve (not shown) to atmospheric pressure can evacuate the liquid 318 without inducing puckering of the die 302. In various embodiments, the suction force can comprise a controlled vacuum in a range of about 10 kPa to 20 kPa below atmospheric pressure, which can be provided by a vacuum regulator (not shown) or venturi device (not shown). Alternatively or additionally, the plate 304 can comprise an integrated heating element (as seen in FIG. 3A) to evaporate the liquid 318. Examples of non-porous materials with a smooth surface with good wetting that can be used in conjunction with the embodiment of FIG. 3B include, for example, silicon with an oxide surface, or an anodized aluminum or other metal surface that can be easily heated to release the die 302.

FIG. 4 is a schematic diagram of a bonding tool 401. The bonding tool 401 may be similar or identical to the bonding tool 401 discussed above in many respects. Accordingly, numerals used to identify features of bonding tool 401 are incremented by 100 to identify certain similar features of the bonding tool 401. For example, as shown in FIG. 4, the bonding tool 401 can include an end effector 415, a die support surface 416, and a liquid layer 418 described above in connection with the bonding tool 301. The bonding tool 401 can include any one or a combination of the features of the bonding tool 301.

As seen in FIG. 4, the bonding tool 401 comprises an end effector 415 and a bond initiation actuator 417 configured to separate the bond initiation region 413 of the die 402 from the die support surface 416 prior to separating other regions of the die 402. In FIG. 4, the actuator 417 can be disposed within a hollow channel 421 of the shaft 406. The actuator 417 can comprise any suitable type of actuator configured to cause a single “point” or region of the die 402 to protrude from the die support surface 416, including, e.g., a rod. The rod can be sized to fit within the channel 421 of the hollow shaft 406. In various embodiments, depending on the lateral dimensions of the die, the rod can have a diameter of less than 5 mm, less than 4 mm, less than 3 mm, less the 2 mm, less than 1000 μm, less than 800 μm , less than 500 μm, or less than 100 μm. In some embodiments, the diameter of the rod can be in a range of 0.5 mm to 5 mm, in a range of 1 mm to 5 mm, or in a range of 1 mm to 4 mm. In various embodiments, the larger the die, the larger the dimension of the contacting portion of the rod, and vice versa. In some embodiments, the rod can comprise a flat head. In other embodiments, the actuator 417 can have a rounded head. In some embodiments, the actuator 417 can comprise a spring (e.g., a shape memory alloy spring) or a piezo-electric actuator. In the illustrated embodiment, the actuator 417 can be centrally located with respect to the die support surface 416. In the illustrated example, the actuator 417 can serve to both initiate contact and bonding at a single bond initiation region 413 and cause release of the die 402 from the adhesion mechanism of the robotic end effector 415 (e.g., the mechanism(s) by which the die 402 is temporarily adhered or attached to the end effector 415). The actuator 417 of FIG. 4 can be used in conjunction with any of the embodiments disclosed herein, and can be used for bond initiation and release as shown, or for bond initiation in conjunction with a separate release mechanism such as the heater 320 of FIG. 3A or liquid vacuum of FIG. 3B. In some embodiments, as explained above, the die support surface 416 can be curved, and a mechanical actuator 417 such as that shown in FIG. 4 can be supplied to initiate contact between the bond initiation region 413 of the die 402 and the substrate 403 prior to release of the die 402.

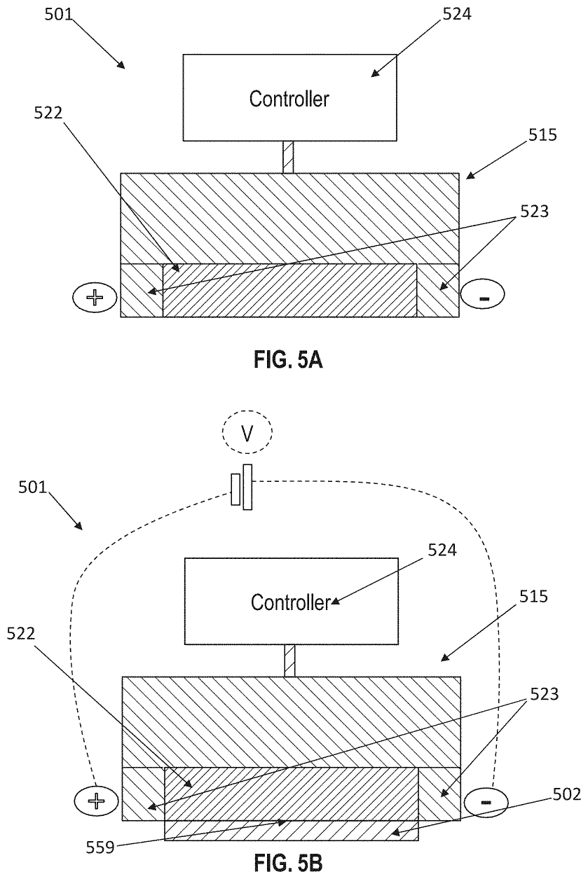

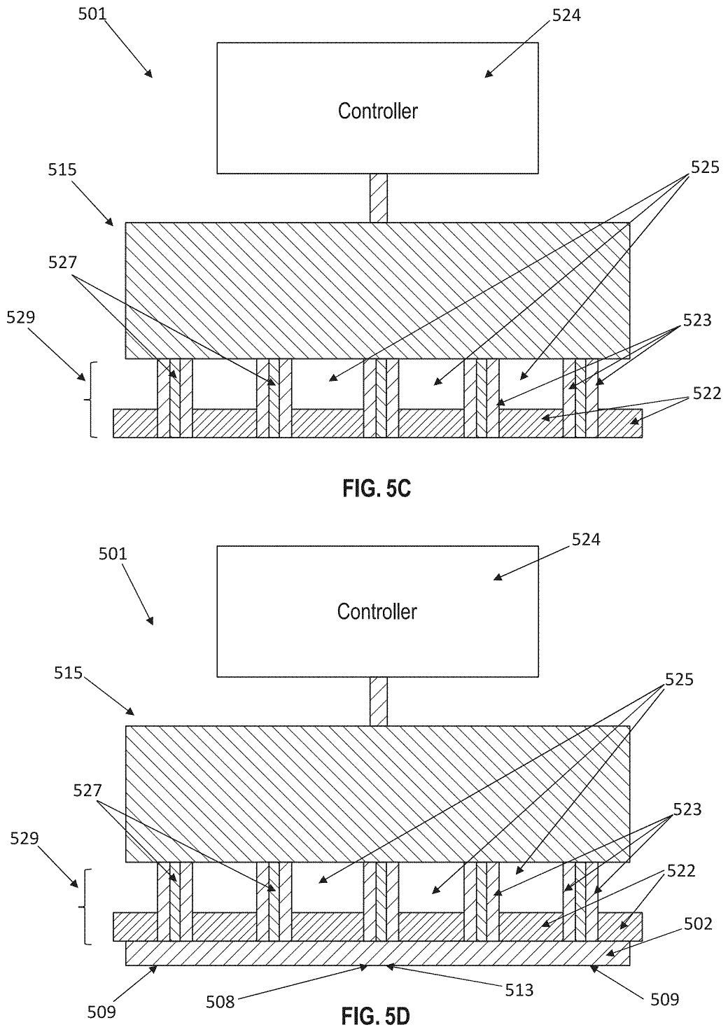

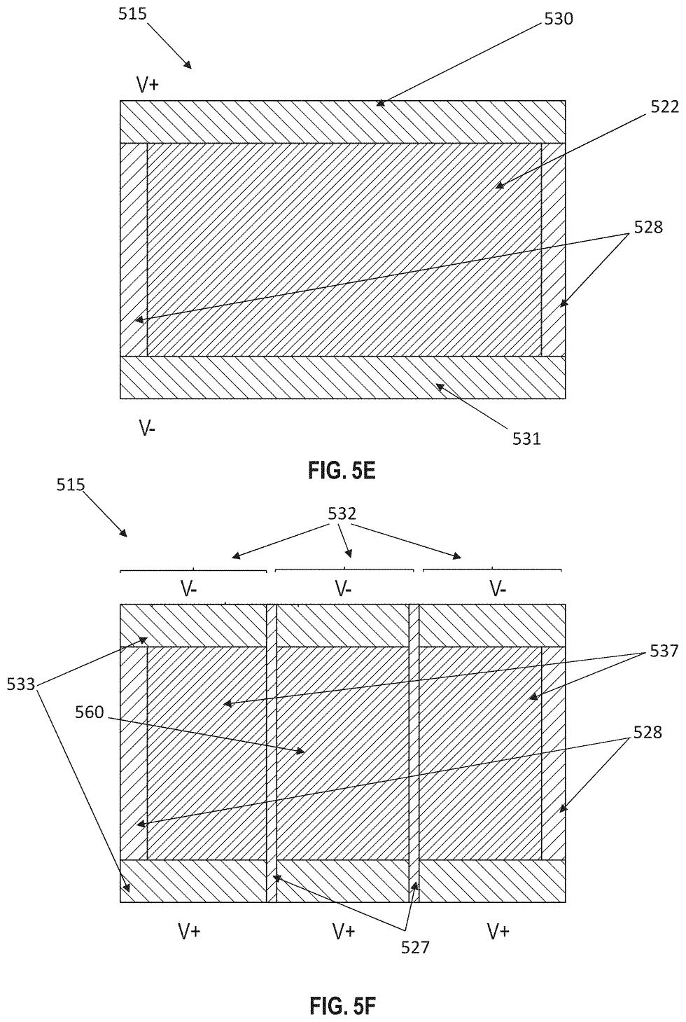

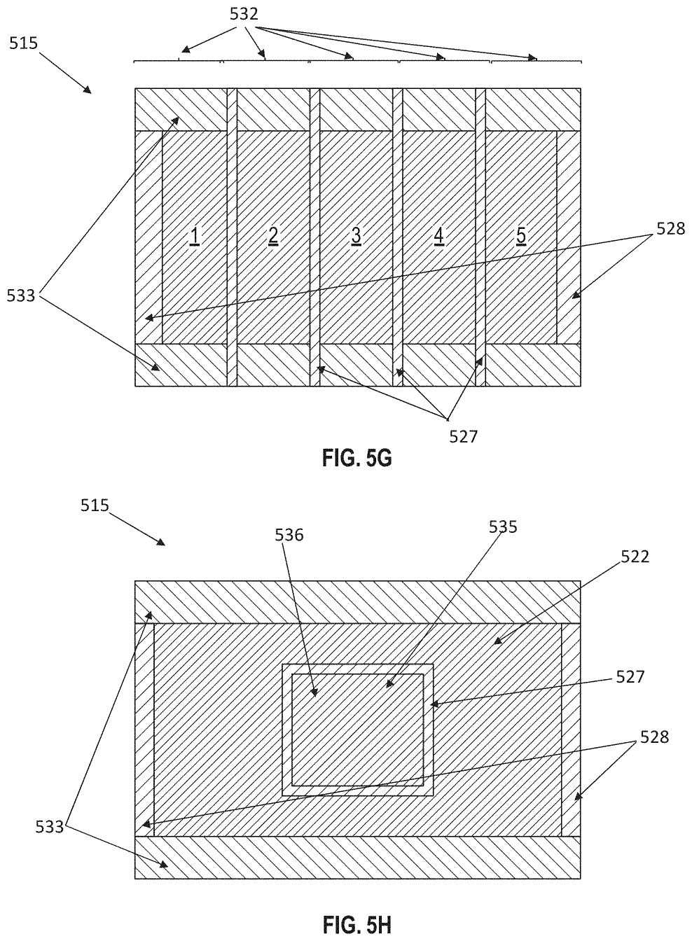

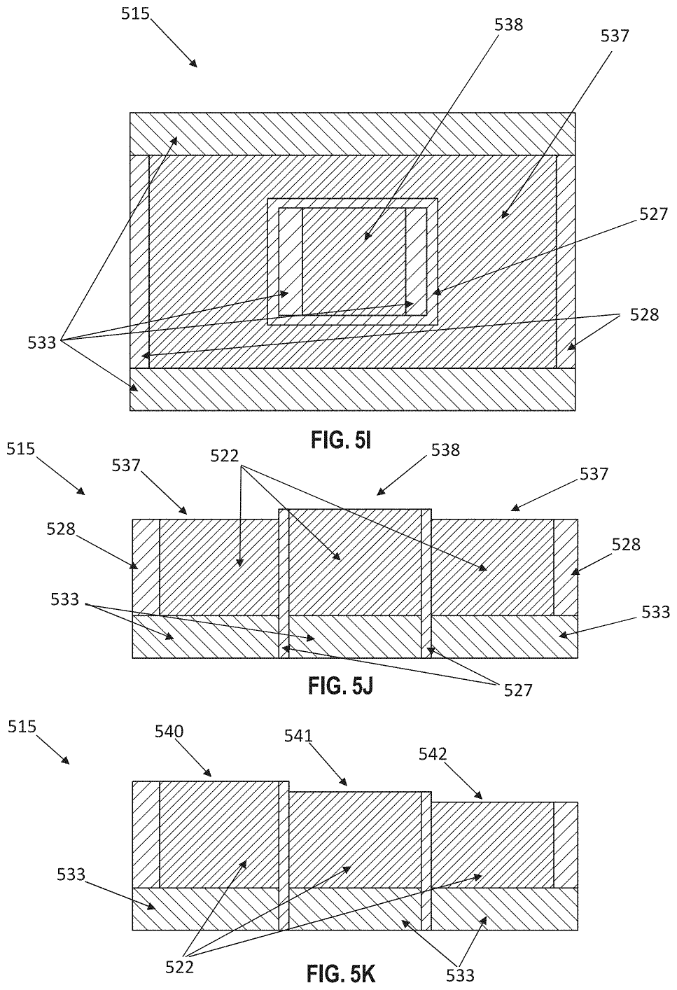

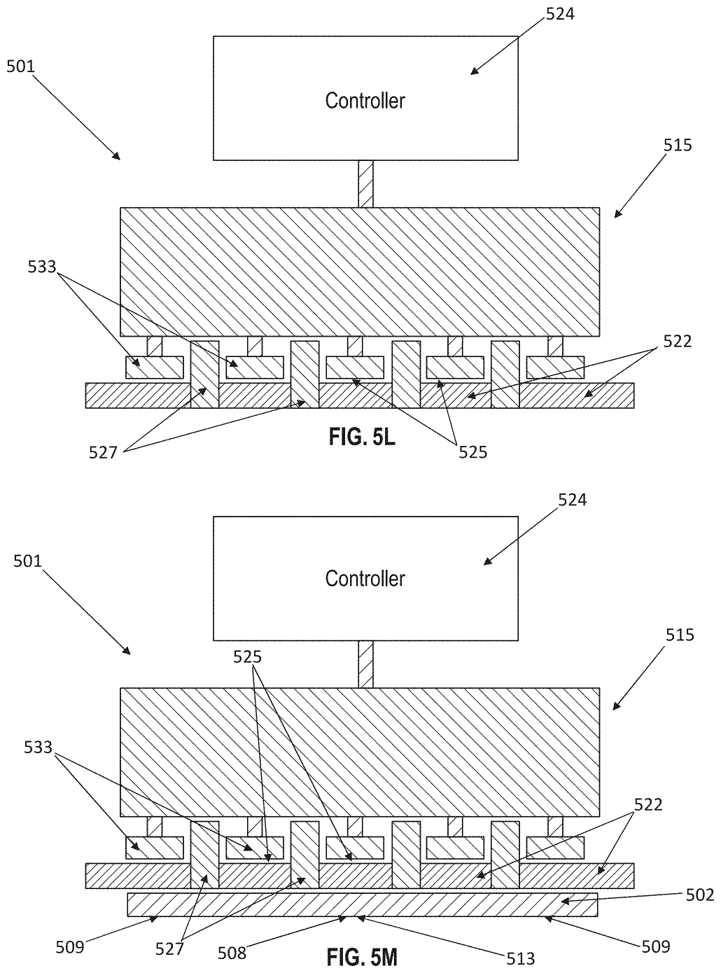

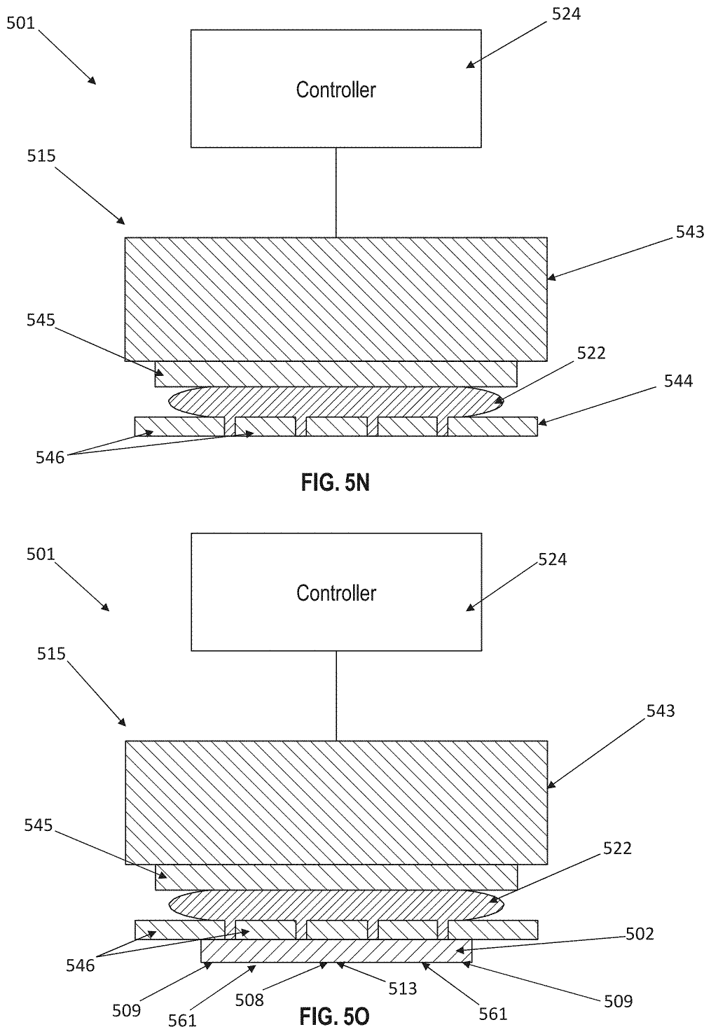

In various embodiments, a controller (e.g., the controller as seen in FIG. 5A) can be provided to control the operation of the bonding tool 401. For example, the controller can include processing circuitry to control at least one of release timing, the heating timing and power, the actuator 417 (e.g., a shape memory spring or piezoelectric actuator), and any other suitable components of the system 400. In some embodiments, one or more sensors (not shown) (e.g., temperature sensors, such as a thermocouple) can be provided to monitor a temperature of the die support surface 416 and/or die 402. The controller can utilize feedback from the measured temperature in order to improve the control of the bonding process.

FIGS. 5A-5O illustrate various embodiments of a bonding tool 501. The bonding tool 501 may be similar or identical to the bonding tools discussed above in many respects. Accordingly, numerals used to identify features of bonding tool 501 are incremented by 100 to identify certain similar features of the bonding tools described above. For example, as shown in FIGS. 5A-5O, the bonding tool 501 can include an end effector 515 and a die support surface 516 described above in connection with the bonding tools previously described. The bonding tool 501 can include any one or a combination of the features of the bonding tools described above.

FIGS. 5A-5M illustrate various embodiments of electrically or magnetically powered single or multiple die pick cells, for applications in picking up singulated dies and bonding the picked die(s) to another substrate. The various arrangements comprise, for example, an electrorheological (Voltage Activated Adhesive—VAA) or magnetorheological (Magnetic Field Activated Adhesive—MFAA) material having rheological properties, such as flow, deformation, and/or adhesion that are strong function(s) of the electric or magnetic field strength imposed upon them. In one embodiment, an electrorheological material (gel) 522, for example, an electrorheological adhesive in which adhesive properties increase with increasing applied electrical voltage and diminish as the applied voltage is reduced, can be disposed between two or more electrodes 523, e.g., a first electrode and a second electrode. FIGS. 5A-5B illustrate a voltage activated adhesive (VAA) layer 522 disposed between two opposing electrodes 523 on an end effector 515. The bonding tool 501 can include a controller 524 comprising a control circuit programmed to apply the voltage on command, e.g., to increase the adhesive properties of the VAA layer 522 to pick up a singulated die 502, as shown in FIG. 5B for bonding the die 502 to another substrate (not shown). After the bonding operation, the applied voltage can be removed or decreased to reduce or eliminate the adhesion between the VAA layer 522 and the backside 559 of the die 502 to be bonded.

FIGS. 5C and 5D illustrate a die bonding tool 501 including an end effector 515 (also referred to herein as a pick head) comprising a zoned release mechanism 529 configured to release the bond initiation region 513 of the die 502 prior to releasing the other regions of the die 502. The pick head 515 comprises segmented multiple zones or cells 525 to enable sequential release of the die 502 from center to edge, or vice versa, to control bond wave propagation and avoid trapping air, thus reducing or eliminating voiding defects in directly bonded substrates (including die to wafer or die to die bonded structures). As illustrated, the bond head 515 can be configured with multiple parallel cells 525, each cell 525 comprising a VAA layer 522 disposed between two electrodes 523 and an electrode spacer 527 isolating the cells 525 from each other. The segmented cells 525 may be independently energized by applying a suitable voltage with the controller 524. The voltages applied to the various cells 525 may be uniform or non-uniform during the bonding operation. In one embodiment, during a bonding operation, for example, a determined voltage may be applied across the various cells 525 to pick the singulated die 502 for attachment to the host substrate (not shown), as shown in FIG. 5D. Upon contact with the host substrate or in very close proximity to the surface of the host substrate, the voltage applied to the inner most cell or cells disposed at the center region of the backside of the die 502 may be increased momentarily to induce the center portion 508 of the die 502 to contact the host surface first. For example, applying voltage to the fluid 522 can increase the adhesion and viscosity of the fluid 522. Applying a higher voltage to the center electrode relative to the outer electrodes can induce bowing of the thin die 502 which can allow the central region 508 of the die 502 to touch the host substrate first. Upon contact between the center 508 of the die 502 and the host substrate or wafer, the voltage applied to the electrode at the center 508 of the die 502 can be dramatically reduced or de-energized (e.g., reduced to zero), while voltage is still momentarily applied to the outer segmented electrodes. The reduction or reduction rate of the voltage at the outer electrodes can be programmed to match the speed of the outwardly-bound bonding wave. Thus, the outer portions 509 of the die 502 can contact the surface of the host substrate 503 last. Thus, as the bonding wave propagates outwardly, the other portion(s) 509 of the die 502 may be released by de-energizing the outer cells (e.g., by reducing the voltage applied to the outer cells). In one embodiment, the voltage applied to the various cells 525 may be graded from the cell disposed at the center of the die 502 to the outer cell during the bonding operation. Thus, the voltage applied to the cells disposed over the center 508 of the die 502, during the initial contact of the die 502 with the host substrate 503, may be higher than the voltage applied to the cell disposed closer to the outer edge 509 of the die.

FIGS. 5E to FIG. 5G illustrate example configurations of a top view of an end effector 515 that includes an electrorheological or magnetorheological material 522. FIG. 5E depicts the disposition of a voltage activated electrorheological or magnetorheological material 522 between a first electrode 530 and a second electrode 531, with insulating spacers 528 provided between the electrodes to provide a space for the electrorheological or magnetorheological material 522. In some applications, the insulating spacer 528 may be omitted. FIG. 5F illustrates a dynamically programmable end effector 515 with a plurality (e.g., three) of cells 532, each cell 532 comprising a pair of electrodes 533and an electrorheological or magnetorheological material 522 (e.g., a VAA layer) disposed between the electrodes 533. The cells 532 can be isolated from each other by an inert insulating material of the electrode spacer 527. The electrodes in any of the present embodiments may be fabricated from an electrically conductive material, which may include copper, nickel, iron, titanium, carbon, tantalium, gold and their various alloys. In some applications, the electrode material may comprise a less expensive conducting material coated with a thinner layer of a more noble material, for example nickel clad over copper, or gold clad over nickel. During a bonding operation, an applied voltage or a programmed voltage may be applied across the plurality of cells 532 to pick the die and bond the die to the host substrate. For example, the voltage applied to the central cell 560 may be different from the voltage applied to the outer cells 537 during the initial contact of the die to the host substrate.

Similarly, FIG. 5G depicts a top view of an end effector 515 with five independently programmable cells 532 (Cell 1, Cell 2, Cell 3, Cell 4 and Cell 5). A programmed voltage may be applied to the individual cells 532 to control the die pick up and the timing of the relative contacts of portions of the dies to the host substrate to control the propagation of the bonding wave between the bonding surface of the die and the bonding surface of the host substrate.

FIG. 5H illustrates a top view of a bonding end effector 515 having a single VAA cell, similar to that of FIG. 5E, except that the die pick up surface of FIG. 5H may include an electrode-free region 535 within the VAA layer 522, which is isolated from the electrical or magnetic field, or from stress. In this embodiment, the die end effector surface comprises a first VAA layer 522 and another material 536 embedded within a portion of the VAA layer 522 and isolated from the VAA layer 522 by an inert or insulating electrode spacer material 527. The electrode spacer 527 can shield the embedded material 536 from the effects of the applied electrical voltage. In one embodiment, the material of the VAA layer 522 can be different from the composition of the embedded electrode-free material 536. The top surface of the embedded material 536 may be higher than the top surface of the VAA layer 522 by less than 200 micros, less than 100 microns, less than 50 microns, or less than 20 microns. Upon the application of a voltage to the cell of FIG. 5H, the singulated die bonds to the VAA layer 522 surrounding the embedded material 536, while the embedded material 536 determines the curvature of the die on the end effector 515. During a bonding operation, the bonding region of the die having the embedded material support on the backside contacts the bonding surface of the host substrate before other portions of the bonding surface of the die. In some embodiments, the electrode spacer 527 may not be used, for example, if the embedded material 536 comprises a non-electrorheological material.

FIG. 5I is a top view of an end effector 515 that is generally similar to the end effector of FIG. 5H, except in FIG. 5I, a larger outer cell 537 surrounds a smaller inner cell 538. Both the outer cell 538 and inner cell 537 may be programmed to pick a die and bond the die on a host substrate while avoiding bonding wave related defects. In one embodiment, ratio of the electric field between the inner cell 538 and the outer cell 537 may be used to control the propagation of the bonding wave during the bonding operation. Also, the ratio of this field may be applied to control the curvature of the die on the surface of the end effector 515. In one embodiment, the electric field applied to the inner cell 538 may be higher than the electric field applied to the outer cell 537. In one embodiment, the electric field applied to the inner cell 538 can be at least 5% higher, at least 10% higher, at least 20% higher, or at least 40% higher than the field applied to the outer cell 537.

FIGS. 5J and 5K are schematic side sections of segmented electrodes 533 on a die bonding end effector 515. As seen in FIG. 5J, the end effector 515 comprises an inner cell 538 higher than the outer cells 537. The top surface of the VAA layer 522 of the inner cell 538 may be higher than the top surface of the VAA layer 522 of the outer cells 537 by less than 50 microns, less than 30 microns, or less than 20 microns. FIG. 5K illustrates segmented electrodes 533 of a die bonding end effector 515 with graded cell heights. In this embodiment, the top surface of the VAA layer 522 of the first cell 540 is higher than the top surface of the VAA layer 522 of the second cell 541, and the height of the second cell 541 is higher than the height of the third cell 542, if a third cell is provided. In other embodiments, for example, only two cells may be provided, with the height of the first cell being higher than the height of the second cell. In addition to utilizing cell programming by the controller, the mechanical profile of the VAA of the array of cells may be applied to control bonding wave propagation during the direct bonding of one substrate to another.

In the illustrated embodiments, the end effector 515 can include an electrorheological or magnetorheological material 522 whose adhesive or attractive properties are responsive to an electrical field or a magnetic field, respectively. In FIGS. 5L-5M, the voltage activated adhesive material (VAA) 522 may be disposed over a first electrode 533 and the VAA material 522 or a layer serving as a second electrode. The VAA material 522 may be rendered cathodic or anodic with respect to the first electrode 533 and vice versa, depending on the nature of the VAA material 522. The bonding tool 501 can include a controller 524 comprising a control circuit programmed to release the bond initiation region 513 from the end effector 515 while continuing to adhere the other regions of the die to the end effector 515, and subsequently release the other regions of the die. In various embodiments, as explained above, the bond initiation region 513 is a central region 508 of the die 502, and the other regions include peripheral regions 509 of the die 502. In other embodiments, the bond initiation region is a peripheral region 509 of the die 502, and the other regions include central regions 508 and opposite peripheral regions of the die 502.

In FIGS. 5L-5M, the dynamically programmable end effector 515 can be configured to releasably secure the die 502 to the die handling tool 501 through dynamic control of the adhesion of the VAA layer 522, or an electrorheological or magnetorheological gel provided between a die 502 and the first electrode 533. FIG. 5L illustrates the end effector 515 of a bonding tool 515, comprising segmented electrodes 533. The electrodes 533 can be separated by insulating electrode spacers 527 and the counter electrode comprising the VAA layer 522. As described above, each segmented cell 525 may be programmed with a single voltage for die pick up and the voltages applied to the separate cells 525 can be controlled in such a manner that the bonding surface of the center 508 of the die 502 contacts the host bonding surface before other portions of the bonding surface of the die 502. In one embodiment, a graded voltage profile can be applied across the array of cells 525, such that the outermost cell on one end has the highest voltage and the outermost cell at the opposite end of the array has a lower voltage.

For example, the end effector 515 can include an upper unit 543 and a lower unit 544, as seen in FIGS. 5N-5O, with the electrorheological or magnetorheological gel (or VAA material) 522 disposed between the upper unit 543 and lower unit 544. In some embodiments, e.g., those that utilize a VAA material, the upper unit 543 can comprise an electrode array 545, and the lower unit 544 can comprise a perforated lower electrode array 546 defining a plurality of electrode zones for applying electric fields to affect adhesive properties of the VAA layer 522 provided between the upper unit 543 and lower unit 544. In some embodiments, e.g., those that utilize a magnetorheological gel, the upper unit 543 can comprise a magnetic unit, and the lower unit 544 can comprise a perforated lower magnetic unit defining a plurality of zones for applying magnetic fields to affect adhesive properties of the material provided between the upper unit 543 and lower unit 544.

As shown in FIG. 5N, for example, the controller 524 can send the end effector 515 a first signal in which the upper unit 543 and lower unit 544 cooperate to apply an electric field or a magnetic field (which may be zero or non-zero) to the fluid 522 such that the fluid 522 has a low adhesion to the die 502 (e.g., an adhesion strength sufficiently low such that the end effector 515 does not lift the die 502). To pick up the die 502, the controller 524 can send the end effector 515 a second signal in which the upper 543 and lower 543 units cooperate to apply an electric field or a magnetic field (which may be zero or non-zero) to the fluid 522 such that the fluid 522 has a higher adhesion to the die 502 (e.g., an adhesion strength sufficiently high such that the end effector 515 lifts the die 502). The end effector 515 can be lowered to cause the die 502 to contact the substrate in a bonding initiation region 513. After contact with the bonding initiation region 513 (e.g., a central region 508 or a side edge 509 of the die), the controller 524 can send a third signal to the end effector 515 to apply an electric field or a magnetic field (which may be zero or non-zero) to permit sequential release of the bond initiation region 513 of the die 502 prior to the other regions of the die 502. For example, for bonding techniques in which the center 508 of the die 502 comprises the bond initiation region 513, the controller 524 can instruct the end effector 515 to place a central region 508 of the end effector 515 in the low adhesion state before placing peripheral region(s) 509 of the end effector 515 in the low adhesion state. There may also be intermediate zones 561 between the central region 508 and the peripheral regions 509. In various embodiments, the bonding tool 501 can include a control circuit for timing a picking the die 502 and for controlling release of the sub-region and other regions of the die 502. The defined zones can depend upon where the bond initiation region 513 is located, and can be arranged to first release the bond initiation region 513 and progressively release regions adjacent to and more remote from the bond initiation region 513 of the die 502, such that a single bond front propagates away from the bond initiation region 513. The zoned release mechanism can be employed in conjunction with a single bond initiation mechanism, such as a curved die support surface, robotic control and/or an actuator to define a single bond initiation region.

Advantageously, the embodiments of FIGS. 5A-5O can hold the die 502 without vacuum force, and can reduce or minimize the advent of puckering shown in FIG. 1B.

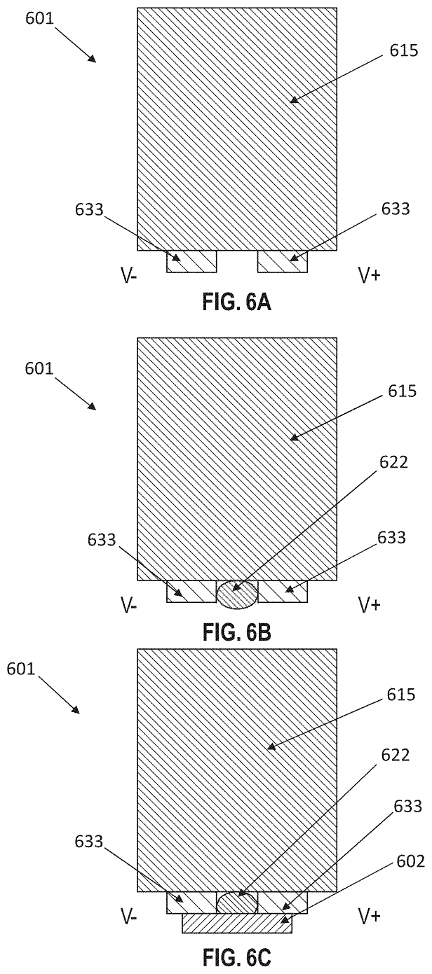

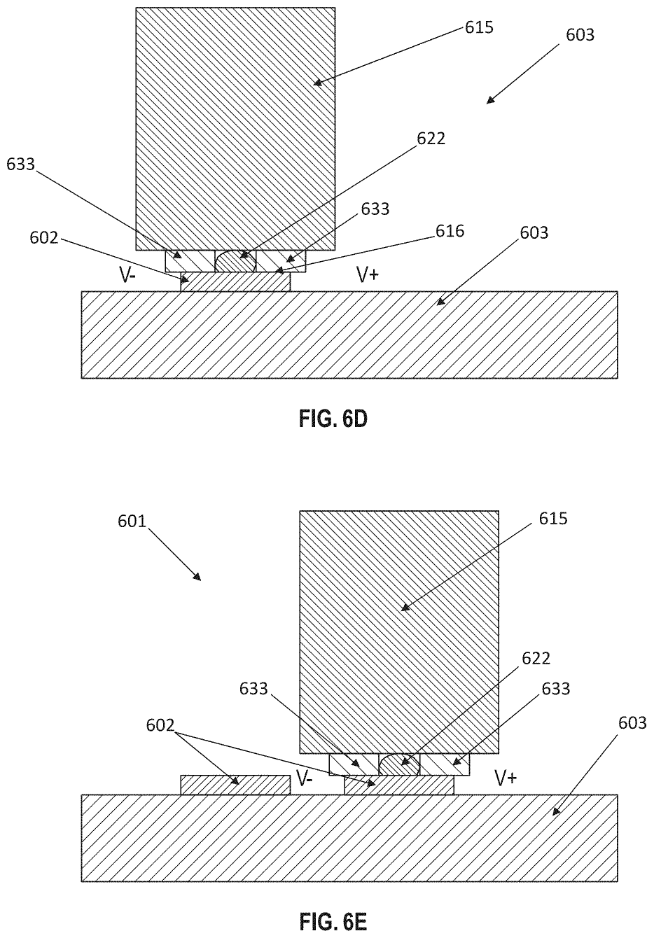

FIGS. 6A-6E illustrate another embodiment of a bonding tool 601. The bonding tool 601 may be similar or identical to the bonding tools discussed above in many respects. Accordingly, numerals used to identify features of bonding tool 601 are incremented by 100 to identify certain similar features of the bonding tools described above. For example, as shown in FIGS. 6A-6E, the bonding tool 601 can include an end effector 615 and a die support surface 616 described above in connection with the bonding tools previously described. The bonding tool 601 can include any one or a combination of the features of the bonding tools described above.

As seen in FIGS. 6A-6E, the bonding tool 601 comprises an end effector 615 which utilizes an electrorheological gel 622 (VAA) or adhesive to directly bond a die 602 to a substrate 603. Unless otherwise noted, the bonding tool 601 of FIGS. 6A-6E may operate in a generally similar manner to the device of FIGS. 5A-5O. In FIGS. 6A-6E, the end effector 615 can comprise a plurality of electrodes 633 spaced apart laterally, as opposed to the vertically separated electrodes of FIGS. 5N-5O. The electrodes 633 can comprise at least a portion of the die support surface 616 of the end effector 615. In FIG. 6C, a voltage can be applied across the electrodes 633 to increase the adhesive properties of the VAA layer 622. The end effector 615 can bond the die 602 to the substrate 603 as explained herein. In FIG. 6D, the die 602 can be released from the end effector 615 by deactivating the electric field to significantly reduce the adhesive properties of the gel 622. In FIG. 6E, additional dies 602 can be bonded to the substrate 603 as desired. The embodiment of FIGS. 6A-6E can combine mechanisms defining a single bond initiation region (such as a curved die support surface, an actuator and/or robotic controls) and/or zoned release mechanisms disclosed herein.

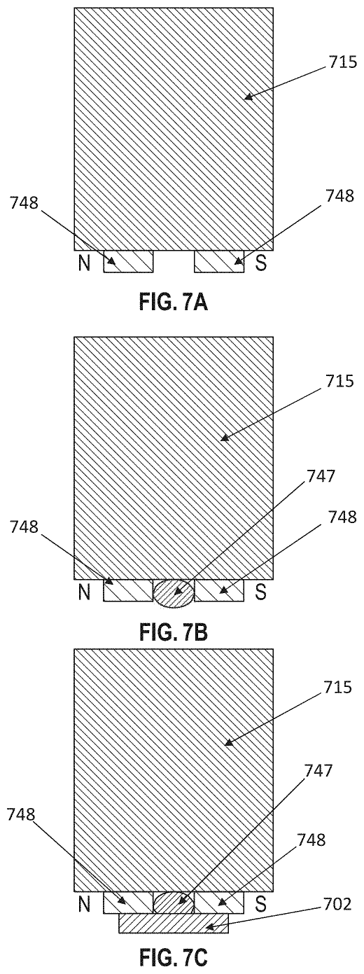

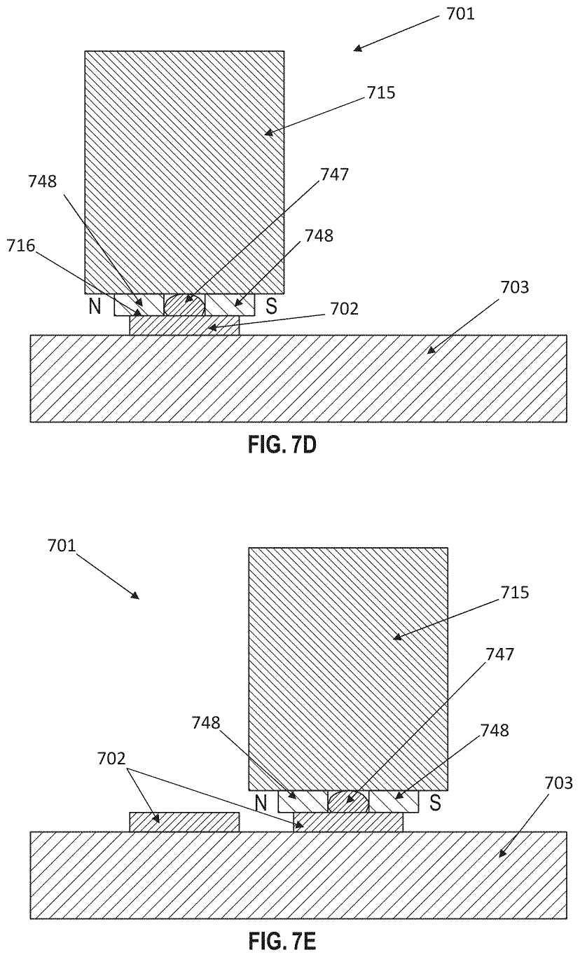

FIGS. 7A-7E illustrate another embodiment of a bonding tool 701. The bonding tool 701 may be similar or identical to the bonding tools discussed above in many respects. Accordingly, numerals used to identify features of bonding tool 701 are incremented by 100 to identify certain similar features of the bonding tools described above. For example, as shown in FIGS. 7A-7E, the bonding tool 701 can include an end effector 715 and a die support surface 716 described above in connection with the bonding tools previously described. The bonding tool 701 can include any one or a combination of the features of the bonding tools described above.

FIGS. 7A-7E illustrate another embodiment of a bonding tool 701 in which the end effector 715 utilizes a magnetorheological gel 747 or adhesive to directly bond a die 702 to a substrate 703. Unless otherwise noted, the bonding tool 701 of FIGS. 7A-7E may operate in a generally similar manner to the device of FIGS. 5A-5O. In FIGS. 7A-7E, the end effector 715 can comprise a plurality of magnets 748 having opposite polarity and spaced apart laterally, as opposed to the vertically separated electrodes of FIGS. 5A-5O. The magnets 748 can comprise at least a portion of the die support surface 716 of the end effector 715. In FIG. 7C, a magnetic field can be applied between the magnets 748 to increase the adhesive properties of the gel 747. The end effector 715 can bond the die 702 to the substrate 703 as explained herein. In FIG. 7D, the die 702 can be released from the end effector 715 by deactivating the magnetic field to significantly reduce the adhesive properties of the gel 747. In FIG. 7E, additional dies 702 can be bonded to the substrate 703 as desired. The embodiment of FIGS. 7A-7E can combine mechanisms defining a single bond initiation region (such as a curved die support surface, an actuator and/or robotic controls) and/or zoned release mechanisms disclosed herein.

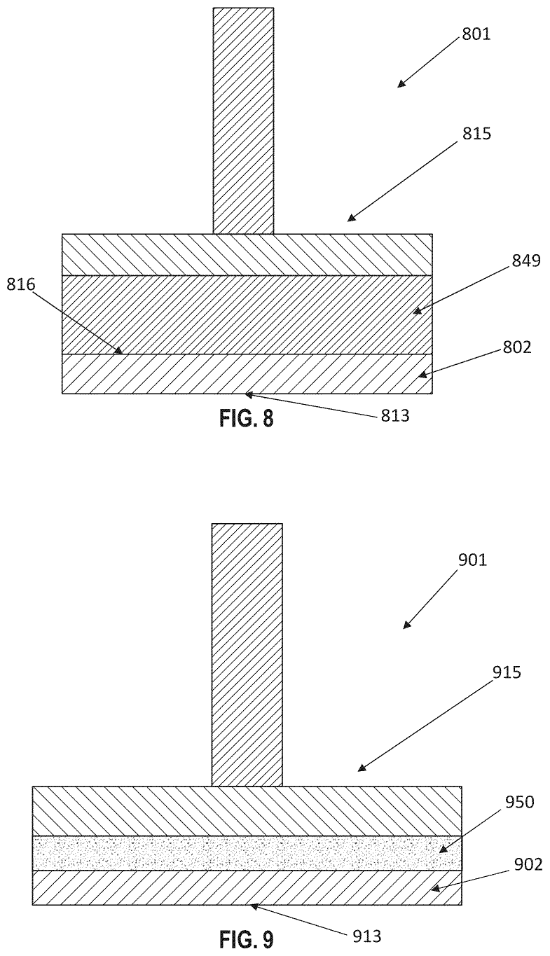

FIG. 8 illustrates another embodiment of a bonding tool 801. The bonding tool 801 may be similar or identical to the bonding tools discussed above in many respects. Accordingly, numerals used to identify features of bonding tool 801 are incremented by 100 to identify certain similar features of the bonding tools described above. For example the bonding tool 801 can include an end effector 815 and a die support surface 816 described above in connection with the bonding tools previously described. The bonding tool 801 can include any one or a combination of the features of the bonding tools described above.

FIG. 8 illustrates another embodiment of a bonding tool 801 including an end effector 815 that releasably secures the die 802 to the die handling tool 801 through an electrostatic attraction between a die support surface 816 of the end effector 815 and the die 802. The bonding tool 801 can comprise an end effector 815 or bond head including an electrostatic chuck 849 with rapid charging and release cycling capability. Charging the chuck 849 can enable picking and transportation of the die 802. Once the die 802 is aligned and placed, a reverse current can be transmitted to neutralize the charge built up on the chuck 849 and on the die 802 to release the die 802 without uncontrolled deformation. In various embodiments, the chuck 849 can comprise a plurality of zones to control bonding wave propagation. For example, with a central bond initiation region 813, multiple electrodes can be arranged in zones surrounding the central bond initiation region 813 arranged or electrically controlled in annular regions to progressively release the central region first and adjacent outer regions in sequence thereafter.

FIG. 9 illustrates another embodiment of a bonding tool 901. The bonding tool 901 may be similar or identical to the bonding tools discussed above in many respects. Accordingly, numerals used to identify features of bonding tool 901 are incremented by 100 to identify certain similar features of the bonding tools described above. For example, the bonding tool 901 can include an end effector 915 and a die support surface 916 described above in connection with the bonding tools previously described. The bonding tool 901 can include any one or a combination of the features of the bonding tools described above.

FIG. 9 illustrates another embodiment of a bonding tool 901 including an end effector 915 that releasably secures the die 902 to the die handling tool 901 using a dry adhesive technology 950 inspired by the dry adhesive properties of gecko feet, which allows it to attach and detach from a surface easily. One commercially available dry adhesive tape 950 is the Setex Gecko Tape produced by nanoGriptech of Pittsburg, Pa. Another example of such a dry adhesive tape 950 is Vertec® Texturized Film (GP-TXF), produced by Gel-Pak of Hayward, Calif. The gecko feet tape 950 can apply an adhesion force between the die 902 and the tape 950 that is in a range of about 1% to 90% of room temperature bond energy, such as about 10%. The tape 950 can support the die 902 during transportation. Once the die 902 is aligned and the bonding is initiated, initially at the bond initiation region 913, the bonding force peels off the die 902 from the gecko feet tape 950 as the bond front propagates. In some embodiments, the bonding tool 901 can include a pin actuator (not shown) for releasing the die 902 and initiating bonding at a single bond initiation region 913. In other embodiments, an optical element (e.g., a laser) (not shown) can be activated to release the die 902. Beneficially, the use of gecko feet tape 950 enables the reuse of the tape 950 over several cycles as opposed to conventional tape. Moreover, the gecko feet tape 950 can be designed to have different levels of adhesion in different regions of the tape 950 so as to provide a phased release of the die 902. For example, in various embodiments, the different levels of adhesion can be provided during fabrication of the tape 950, which may be made using photolithography/electron beam lithography, plasma etching, deep reactive ion etching (DRIE), chemical vapor deposition (CVD), micro-molding, roll-to-roll processes, etc to produce the synthetic setae. Adhesion force can be varied by varying the size and density of the synthetic setae on the surface of the tape 950 during photo patterning.

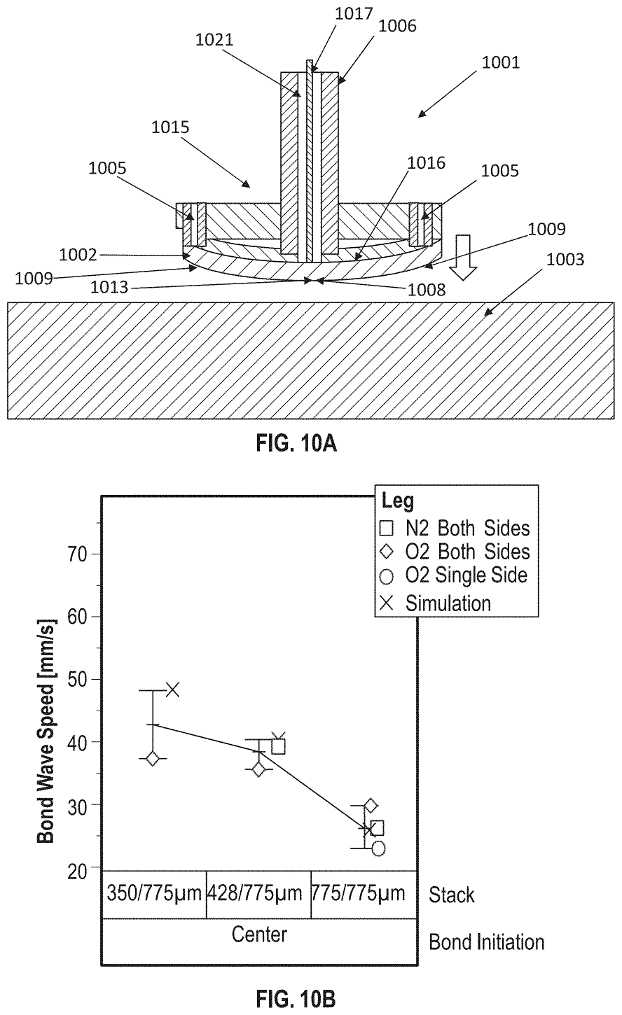

FIG. 10A illustrates another embodiment of a bonding tool 1001. The bonding tool 1001 may be similar or identical to the bonding tools discussed above in many respects. Accordingly, numerals used to identify features of bonding tool 1001 are incremented by 100 to identify certain similar features of the bonding tools described above. For example, the bonding tool 1001 can include an end effector 1015 and a die support surface 1016 described above in connection with the bonding tools previously described. The bonding tool 1001 can include any one or a combination of the features of the bonding tools described above.

FIG. 10A is a schematic diagram of a bonding tool 1001 according to another embodiment. In FIG. 10A, the end effector 1015 can comprise a hollow shaft 1006 with a channel 1021 therethrough that receives a release actuator 1017. The end effector 1015 can also include one or a plurality of vacuum channels 1005 at a periphery of the end effector 1015. The end effector 1015 can releasably secure the die 1002 to the die handling tool 1001 through vacuum suction between a die support surface 1016 of the end effector 1015 and the die 1002. In the embodiment of FIG. 10A, the die support surface 1016 comprises vacuum channels 1005 at the periphery only. Thus, in FIG. 10A, during bonding or die transport, the central channel 1021 may not apply a vacuum force to the die 1002, such that the center of the end effector 1015 does not apply a suction force to the die 1002. In some embodiments, the die support surface 1016 comprises zoned vacuum channels for controlled release of the bond initiation region 1013 of the die 1002 prior to the other regions of the die. As shown, and as explained above, the die support surface 1016 can be curved. After the bond initiation region 1013 (e.g., the central region 1008 of the die in FIG. 10A) contacts the substrate 1003, the actuator 1017 can be configured to separate the bond initiation region 1013 of the die 1002 from the die support surface 1016 prior to separating other regions of the die 1002.

For example, in FIG. 10A, a vacuum can be applied to the vacuum channel(s) 1005 along the periphery of the die support surface 1016 to support the edge 1009 of the die 1002. In FIG. 10A, no vacuum is applied to the central channel 1021. The die 1002 can be transported and/or aligned with the substrate 1003 with the vacuum activated to the peripheral channels 1005. The shaft 1006 or shank of the bonding tool 1001 can be moved downward to a preset height, which may be higher than any protruding points on the die 1002 supported by the end effector 1015. Once suitably aligned, the central release actuator 1017 can be activated (e.g., by the controller) to apply a force to the bond initiation region 1013 of the die 1002 (e.g., a central region 1008 of the die 1002) to initiate bonding and to allow the bonding wave to travel outwardly. The peripheral vacuum channels 1005 may remain activated to prevent the edges 1009 of the die 1002 from bonding first and slowing the bonding wave. The release of the edge 1009 of the die 1002 may be timed to allow the bonding process to complete, which may take tens or hundreds of milliseconds according to some embodiments. FIG. 10B is a chart illustrating bond wave speed for various conditions (See “Low temperature Direct Bonding of SiN and SiO interfaces for packaging applications”, by Xavier F. Bruna, Jürgen Burggrafb, Barb Ruxandra-Aidab, Christian Mühlstätterb, 2000 IEEE 70th Electronic Components and Technology Conference (ECTC), p182).

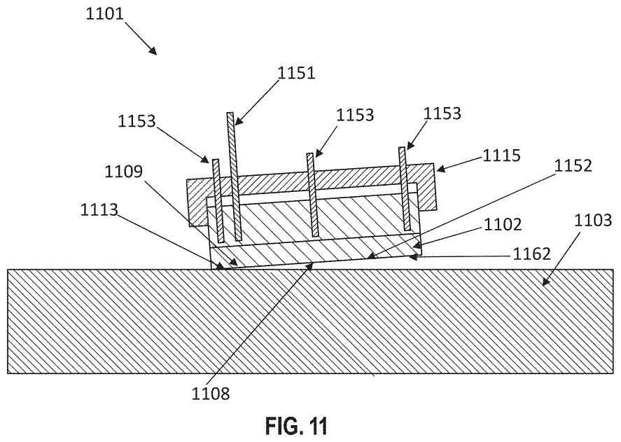

FIG. 11 illustrates another embodiment of a bonding tool 1101. The bonding tool 1101 may be similar or identical to the bonding tools discussed above in many respects. Accordingly, numerals used to identify features of bonding tool 1101 are incremented by 100 to identify certain similar features of the bonding tools described above. For example the bonding tool 1101 can include an end effector 1115 and a die support surface 1116 described above in connection with the bonding tools previously described. The bonding tool 1101 can include any one or a combination of the features of the bonding tools described above.

FIG. 11 illustrates another embodiment of a bonding tool 1101 with multi-stage vacuum control with bonding line initiation. In FIG. 11, the end effector 1115can comprise a bond initiation plate 1151 configured to provide a timed release of the die 1102 during bonding. The bond initiation plate 1151 can be positioned to cause the die 1102 to contact the substrate 1103 only at the bond initiation region 1113 before other regions of the die 1102. The angle between the die bond tool surface 1152 and the host substrate 1103 surface is exaggerated for purposes of illustration. In the embodiment of FIG. 11, the bond initiation plate 1152 can be provided at or near the edge 1109 of the die 1102 such that the edge 1109 of the die 1102 comprises the bond initiation region 1113. The bond can propagate from the die edge 1109 at the bond initiation region 1113 to the opposite edge 1162 of the die 1102. In FIG. 11, therefore, the bonding initiation region 1113 can comprise the single-point or single-region bond in which the die 1102 initially contacts the substrate 1103. The bonding wave can propagate to the opposing edge 1162 without trapping air or creating voids along the bond interface. Multiple vacuum zones 1153 are provided and programmed to release the bond initiation region 1113 first, central regions 1108 second, and opposite edge regions 1162 third. While three zones 1153 are illustrated, the skilled artisan will appreciate that any suitable number of zones can be employed, including two, four, five, six, or more.

### EXAMPLES OF DIRECT BONDING METHODS AND DIRECTLY BONDED STRUCTURES

Various embodiments disclosed herein relate to directly bonded structures in which two elements can be directly bonded to one another without an intervening adhesive. Two or more electronic elements, which can be semiconductor elements (such as integrated device dies, wafers, etc.), may be stacked on or bonded to one another to form a bonded structure. Conductive contact pads of one element may be electrically connected to corresponding conductive contact pads of another element. Any suitable number of elements can be stacked in the bonded structure. The contact pads may comprise metallic pads formed in a nonconductive bonding region, and may be connected to underlying metallization, such as a redistribution layer (RDL).

In some embodiments, the elements are directly bonded to one another without an adhesive. In various embodiments, a non-conductive or dielectric material of a first element can be directly bonded to a corresponding non-conductive or dielectric field region of a second element without an adhesive. The non-conductive material can be referred to as a nonconductive bonding region or bonding layer of the first element. In some embodiments, the non-conductive material of the first element can be directly bonded to the corresponding non-conductive material of the second element using dielectric-to-dielectric bonding techniques. For example, dielectric-to-dielectric bonds may be formed without an adhesive using the direct bonding techniques disclosed at least in U.S. Pat. Nos. 9,564,414; 9,391,143; and 10,434,749, the entire contents of each of which are incorporated by reference herein in their entirety and for all purposes. Suitable dielectric materials for direct bonding include but are not limited to inorganic dielectrics, such as silicon oxide, silicon nitride, or silicon oxynitride, or can include carbon, such as silicon carbide, silicon oxycarbonitride, silicon carbonitride or diamond-like carbon. In some embodiments, the dielectric materials do not comprise polymer materials, such as epoxy, resin or molding materials.

In various embodiments, hybrid direct bonds can be formed without an intervening adhesive. For example, dielectric bonding surfaces can be polished to a high degree of smoothness. The bonding surfaces can be cleaned and exposed to a plasma and/or etchants to activate the surfaces. In some embodiments, the surfaces can be terminated with a species after activation or during activation (e.g., during the plasma and/or etch processes). Without being limited by theory, in some embodiments, the activation process can be performed to break chemical bonds at the bonding surface, and the termination process can provide additional chemical species at the bonding surface that improves the bonding energy during direct bonding. In some embodiments, the activation and termination are provided in the same step, e.g., a plasma or wet etchant to activate and terminate the surfaces. In other embodiments, the bonding surface can be terminated in a separate treatment to provide the additional species for direct bonding. In various embodiments, the terminating species can comprise nitrogen. Further, in some embodiments, the bonding surfaces can be exposed to fluorine. For example, there may be one or multiple fluorine peaks near layer and/or bonding interfaces. Thus, in the directly bonded structures, the bonding interface between two dielectric materials can comprise a very smooth interface with higher nitrogen content and/or fluorine peaks at the bonding interface. Additional examples of activation and/or termination treatments may be found throughout U.S. Pat. Nos. 9,564,414; 9,391,143; and 10,434,749, the entire contents of each of which are incorporated by reference herein in their entirety and for all purposes.

In various embodiments, conductive contact pads of the first element can also be directly bonded to corresponding conductive contact pads of the second element. For example, a hybrid direct bonding technique can be used to provide conductor-to-conductor direct bonds along a bond interface that includes covalently direct bonded dielectric-to-dielectric surfaces, prepared as described above. In various embodiments, the conductor-to-conductor (e.g., contact pad to contact pad) direct bonds and the dielectric-to-dielectric hybrid bonds can be formed using the direct bonding techniques disclosed at least in U.S. Pat. Nos. 9,716,033 and 9,852,988, the entire contents of each of which are incorporated by reference herein in their entirety and for all purposes.

For example, dielectric bonding surfaces can be prepared and directly bonded to one another without an intervening adhesive as explained above. Conductive contact pads (which may be surrounded by nonconductive dielectric field regions) may also directly bond to one another without an intervening adhesive. In some embodiments, the respective contact pads can be recessed below exterior (e.g., upper) surfaces of the dielectric field or nonconductive bonding regions, for example, recessed by less than 30 nm, less than 20 nm, less than 15 nm, or less than 10 nm, for example, recessed in a range of 2 nm to 20 nm, or in a range of 4 nm to 10 nm. The nonconductive bonding regions can be directly bonded to one another without an adhesive at room temperature in some embodiments in the bonding tool described herein and, subsequently, the bonded structure can be annealed. Annealing can be performed in a separate apparatus. Upon annealing, the contact pads can expand and contact one another to form a metal-to-metal direct bond. Beneficially, the use of hybrid bonding techniques, such as Direct Bond Interconnect, or DBI®, available commercially from Adeia of San Jose, Calif., can enable high density of pads connected across the direct bond interface (e.g., small or fine pitches for regular arrays). In some embodiments, the pitch of the bonding pads, or conductive traces embedded in the bonding surface of one of the bonded elements, may be less 40 microns or less than 10 microns or even less than 2 microns. For some applications the ratio of the pitch of the bonding pads to one of the dimensions of the bonding pad is less than 5, or less than 3 and sometimes desirably less than 2. In other applications the width of the conductive traces embedded in the bonding surface of one of the bonded elements may range between 0.3 to 5 microns. In various embodiments, the contact pads and/or traces can comprise copper, although other metals may be suitable.

Thus, in direct bonding processes, a first element can be directly bonded to a second element without an intervening adhesive. In some arrangements, the first element can comprise a singulated element, such as a singulated integrated device die. In other arrangements, the first element can comprise a carrier or substrate (e.g., a wafer) that includes a plurality (e.g., tens, hundreds, or more) of device regions that, when singulated, form a plurality of integrated device dies. In embodiments described herein, whether a die or a wafer, the first element can be considered a host substrate and is mounted on a support in the bonding tool to receive the second element from a pick-and-place or robotic end effector. The second element of the illustrated embodiments comprises a die. In other arrangements, the second element can comprise a carrier or a flat panel (e.g., a wafer).

As explained herein, the first and second elements can be directly bonded to one another without an adhesive, which is different from a deposition process. In one application, a width of the first element in the bonded structure can be similar to a width of the second element. In some other embodiments, a width of the first element in the bonded structure can be different from a width of the second element. The width or area of the larger element in the bonded structure may be at least 10% larger than the width or area of the smaller element. The first and second elements can accordingly comprise non-deposited elements. Further, directly bonded structures, unlike deposited layers, can include a defect region along the bond interface in which nanovoids are present. The nanovoids may be formed due to activation of the bonding surfaces (e.g., exposure to a plasma). As explained above, the bond interface can include concentration of materials from the activation and/or last chemical treatment processes. For example, in embodiments that utilize a nitrogen plasma for activation, a nitrogen peak can be formed at the bond interface. In embodiments that utilize an oxygen plasma for activation, an oxygen peak can be formed at the bond interface. In some embodiments, the bond interface can comprise silicon oxynitride, silicon oxycarbonitride, or silicon carbonitride. As explained herein, the direct bond can comprise a covalent bond, which is stronger than van Der Waals bonds. The bonding layers can also comprise polished surfaces that are planarized to a high degree of smoothness. For example, the bonding layers may have a surface roughness of less than 2 nm root mean square (RMS) per micron, or less than 1 nm RMS per micron.

In various embodiments, metal-to-metal bonds between the contact pads in direct hybrid bonded structures can be joined such that conductive features grains, for example copper grains on the conductive features grow into each other across the bond interface. In some embodiments, the copper can have grains oriented along the 111 crystal plane for improved copper diffusion across the bond interface. The bond interface can extend substantially entirely to at least a portion of the bonded contact pads, such that there is substantially no gap between the nonconductive bonding regions at or near the bonded contact pads. In some embodiments, a barrier layer may be provided under the contact pads (e.g., which may include copper). In other embodiments, however, there may be no barrier layer under the contact pads, for example, as described in US 2019/0096741, which is incorporated by reference herein in its entirety and for all purposes.

In one embodiment, a system for direct bonding can include: a substrate support configured to hold a substrate for direct bonding; and a bonding tool (also referred to as a die handling tool) including an end effector configured to hold a die and bring the die into contact with the substrate supported on the substrate support, the end effector configured to initiate contact between the substrate and a bond initiation region of the die and to subsequently allow contact between the substrate and other regions of the die.

In some embodiments, the end effector is configured to support a rectangular die. In some embodiments, the end effector is configured to support a die having a thickness in a range of 10 μm to 800 μm. In some embodiments, the end effector comprises a die support surface and an actuator, wherein the actuator is configured to separate the bond initiation region of the die from the die support surface prior to separating other regions of the die. In some embodiments, the actuator comprises a rod with a diameter of less than 3 mm. In some embodiments, the rod comprises a rounded head. In some embodiments, the actuator comprises a spring. In some embodiments, the actuator comprises a piezo-electric actuator. In some embodiments, the actuator is centrally located with respect to the die support surface. In some embodiments, the end effector comprises a die support surface that is curved such that a central region of the die support surface protrudes relative to peripheral regions of the die support surface, the central region configured to support the bond initiation region of the die. In some embodiments, the end effector comprises a zoned release mechanism configured to release the bond initiation region of the die prior to releasing the other regions of the die. In some embodiments, the system can include a control circuit programmed to release the bond initiation region from the end effector while continuing to adhere the other regions of the die to the end effector, and subsequently release the other regions of the die. In some embodiments, the bond initiation region is a central region of the die, and the other regions include peripheral regions of the die. In some embodiments, the bond initiation region is a peripheral region of the die, and the other regions include central regions and opposite peripheral regions of the die. In some embodiments, the bond initiation region is a central spine of the long axis of the die, and the other regions include regions on both opposite regions of the die. In some embodiments, the end effector releasably secures the die to the die handling tool through capillary action of a layer of liquid provided between a die support surface of the end effector and the die. In some embodiments, the end effector comprises a heater configured to evaporate at least a portion of the layer of liquid for releasing the die. In some embodiments, the heater is embedded in a porous ceramic material die support surface of the end effector comprises a porous ceramic material. In some embodiments, the end effector comprises a vacuum source communicating with the layer of liquid for releasing the die. In some embodiments, the end effector comprises a liquid dispensing port to supply the liquid between the die support surface and the die. In some embodiments, the die support surface comprises a smooth non-porous material. In some embodiments, the die support surface is curved and a mechanical actuator is supplied to initiate contact between the bond initiation region of the die and the substrate prior to release of the die. In some embodiments, the end effector releasably secures the die to the die handling tool through adhesion of an electrorheological or magnetorheological material provided between a die support surface of the end effector and the die. In some embodiments, the end effector further comprising an upper electrode or magnetic unit and a perforated lower electrode or magnetic unit defining a plurality of zones of for applying electric or magnetic fields to affect adhesive properties of the gel provided between the upper and lower units and permit sequential release of the bond initiation region of the die prior to the other regions of the die. In some embodiments, the system can include a control circuit for timing a picking the die and for controlling release of the sub-region and other regions of the die. In some embodiments, the end effector releasably secures the die to the die handling tool through an electrostatic attraction between a die support surface of the end effector and the die. In some embodiments, the end effector defines a plurality of zones for applying the electrostatic attraction. In some embodiments, the system can include a control circuit for timing picking the die and for controlling release of the bond initiation region and other regions of the die. In some embodiments, the end effector releasably secures the die to the die handling tool using a dry adhesive. In some embodiments, the system can include a plurality of pin actuators for releasing the die. In some embodiments, the system can include a control circuit for timing a picking the die and for controlling release of the bond initiation region and other regions of the die. In some embodiments, the end effector releasably secures the die to the die handling tool through vacuum suction between a die support surface of the end effector and the die. In some embodiments, the die support surface comprises vacuum channels at the periphery only. In some embodiments, the die support surface comprises zoned vacuum channels for controlled release of the bond initiation region of the die prior to the other regions of the die. In some embodiments, the die support surface is curved. In some embodiments, the system can include an actuator, wherein the actuator is configured to separate the bond initiation region of the die from the die support surface prior to separating other regions of the die. In some embodiments, the die handling tool is configured to bond the die to the substrate without heating and without pressure beyond bringing the die and substrate into contact. In some embodiments, the die handling tool further comprises a height position sensor and a control circuit configured to halt downward movement of the end effector prior to contact with the substrate and subsequently initiating contact between the bond initiation region of the die and the substrate. In some embodiments, the end effector is configured to initiate contact between the substrate and only the bond initiation region of the die.

In another embodiment, a method for direct bonding is disclosed. The method can include: supporting a substrate on a substrate support; supporting a die with a die handling tool configured to initiate contact between a bond initiation region of the die and the substrate; and contacting the substrate with only the bond initiation region of a die.

In some embodiments, the method can include propagating a bond front from the bond initiation region to remaining regions of the die. In some embodiments, the substrate comprises a wafer and the die has a rectangular shape. In some embodiments, the die handling tool comprises a curved die supporting surface with a peak supporting the bond initiation region. In some embodiments, contacting the substrate comprises activating an actuator of the die handling tool to extend the bond initiation region of the die. In some embodiments, the method can include, after contacting the substrate with the bond initiation region of the die, releasing peripheral regions of the die from the die handling tool. In some embodiments, the die handling tool comprises a zoned die retention mechanism and a control circuit to ensure contact between the bond initiation region of the die and the substrate prior to release of other regions of the die. In some embodiments, contacting is conducted without heating to directly and covalently bond non-conductive regions of the die and substrate, further comprising subsequently annealing the die and substrate. In some embodiments, annealing expands conductive features of the die and substrate across a gap into contact with one another to directly hybrid bond the die and the substrate. In some embodiments, supporting the die with the die handling tool comprises electrostatically attracting the die to a die supporting surface of the die handling tool. In some embodiments, supporting the die with the die handling tool comprises attracting the die to a die supporting surface by capillary action with a liquid layer between the die and the die supporting surface. In some embodiments, the method can include releasing the die by heating the liquid layer. In some embodiments, the method can include releasing the die by applying a vacuum to suction the liquid layer. In some embodiments, supporting the die with the die handling tool comprises attracting the die to a die supporting surface by adhesion with an electrorheological or magnetorheological gel between the die and the die supporting surface. In some embodiments, supporting the die with the die handling tool comprises attracting the die to a die supporting surface by applying a vacuum between the die and the die supporting surface.

In another embodiment, a system for direct bonding can include: a die handling tool including an end effector configured to hold a die and bring the die into contact with a substrate supported on a substrate support, the end effector comprising a zoned release mechanism configured to release a bond initiation region of the die prior to releasing other regions of the die; and a controller in electrical communication with the die handling tool, the controller including a control circuit programmed to release the bond initiation region from the end effector while continuing to adhere the other regions of the die to the end effector, and to subsequently release the other regions of the die.

In some embodiments, the bond initiation region is a central region of the die, and the other regions include peripheral regions of the die. In some embodiments, the bond initiation region is a peripheral region of the die, and the other regions include central regions and opposite peripheral regions of the die. In some embodiments, the end effector releasably secures the die to the die handling tool through adhesion of an electrorheological or magnetorheological gel provided between a die support surface of the end effector and the die. In some embodiments, the end effector releasably secures the die to the die handling tool through an electrostatic attraction between a die support surface of the end effector and the die. In some embodiments, the end effector releasably secures the die to the die handling tool through vacuum suction between a die support surface of the end effector and the die. In some embodiments, the die support surface comprises vacuum channels at the periphery only. In some embodiments, the zoned release mechanism comprises zoned vacuum channels for controlled release of the bond initiation region of the die prior to the other regions of the die. In some embodiments, the die support surface is curved. In some embodiments, the system can include an actuator, wherein the actuator is configured to separate the bond initiation region of the die from the die support surface prior to separating other regions of the die.

In another embodiment, a system for direct bonding can include: a substrate support configured to hold a substrate for direct bonding; and a die handling tool including an end effector configured to hold a die with a voltage activated cell and to bring the die into contact with the substrate, the end effector configured to initiate contact between the substrate and a bond initiation region of the die and to subsequently allow contact between the substrate and other regions of the die.

In some embodiments, the end effector includes more than one voltage activated cell to support the die and control the contact between the die and the host substrate. In some embodiments, the end effector includes more than one voltage activated cell to support the die, the cells being programmed to control the propagation of bonding wave between the die and the substrate when the contact between the die and the substrate is established.

In another embodiment, a method for direct bonding is disclosed. The method can include: supporting a substrate on a substrate support; supporting a die with an end effector of a die handling tool the end effector comprising a zoned release mechanism; contacting the substrate with only the bond initiation region of a die; releasing the bond initiation region of the die from the zoned release mechanism of the end effector while the end effector continues to adhere to other regions of the die; and after releasing the bond initiation region, releasing the other regions of the die from the end effector.

In some embodiments, releasing the bond initiation region of the die comprises transmitting a signal from a controller to the zoned release mechanism to release the bond initiation region from the end effector.

In another embodiment, a method for direct bonding is disclosed. The method can include: supporting a substrate on a substrate support; supporting a die with an end effector of a die handling tool, the end effector comprises at least one voltage activated cell; contacting the substrate with only a bond initiation region of a die; and after contacting the substrate with only the bond initiation region, allowing contact between the substrate and other regions of the die.

In some embodiments, allowing contact between the substrate and other regions of the die comprises transmitting a signal from a controller to a plurality of voltage activated cells to control contact between the substrate and other regions of the die. In some embodiments, contacting the substrate with a bond initiation region of a die comprises transmitting a signal from a controller to a plurality of voltage activated cells to control the propagation of bonding wave between the die and the substrate.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A method for direct bonding, comprising:
supporting a substrate on a substrate support;
supporting a die with a die handling tool configured to initiate contact between a bond initiation region of the die and the substrate; and
contacting the substrate with only the bond initiation region of a die.

2. The method of claim 1, further comprising propagating a bond front from the bond initiation region to remaining regions of the die.

3. The method of claim 1, wherein the substrate comprises a wafer and the die has a rectangular shape.

4. The method of claim 1, wherein the die handling tool comprises a curved die supporting surface with a peak supporting the bond initiation region.

5. The method of claim 1, wherein contacting the substrate comprises activating an actuator of the die handling tool to extend the bond initiation region of the die.

6. The method of claim 1, further comprising, after contacting the substrate with the bond initiation region of the die, releasing peripheral regions of the die from the die handling tool.

7. The method of claim 1, wherein the die handling tool comprises a zoned die retention mechanism and a control circuit to ensure contact between the bond initiation region of the die and the substrate prior to release of other regions of the die.

8. The method of claim 1, wherein contacting is conducted without heating to directly and covalently bond non-conductive regions of the die and substrate, further comprising subsequently annealing the die and substrate.

9. The method of claim 8, wherein annealing expands conductive features of the die and substrate across a gap into contact with one another to directly hybrid bond the die and the substrate.

10. The method of claim 1, wherein supporting the die with the die handling tool comprises electrostatically attracting the die to a die supporting surface of the die handling tool.

11. The method of claim 1, wherein supporting the die with the die handling tool comprises attracting the die to a die supporting surface by capillary action with a liquid layer between the die and the die supporting surface.

12. The method of claim 11, further comprising releasing the die by heating the liquid layer.

13. The method of claim 11, further comprising releasing the die by applying a vacuum to suction the liquid layer.

14. The method of claim 1, wherein supporting the die with the die handling tool comprises attracting the die to a die supporting surface by adhesion with an electrorheological or magnetorheological gel between the die and the die supporting surface.

15. The method of claim 1, wherein supporting the die with the die handling tool comprises attracting the die to a die supporting surface by applying a vacuum between the die and the die supporting surface.

16. A method for direct bonding: comprising:
supporting a substrate on a substrate support;
supporting a die with an end effector of a die handling tool, the end effector comprising a zoned release mechanism;
contacting the substrate with only the bond initiation region of a die;
releasing the bond initiation region of the die from the zoned release mechanism of the end effector while the end effector continues to adhere to other regions of the die; and
after releasing the bond initiation region, releasing the other regions of the die from the end effector.

17. The method of claim 16, wherein releasing the bond initiation region of the die comprises transmitting a signal from a controller to the zoned release mechanism to release the bond initiation region from the end effector.

18. A method for direct bonding: comprising:
supporting a substrate on a substrate support;
supporting a die with an end effector of a die handling tool, the end effector comprising at least one voltage activated cell;
contacting the substrate with only a bond initiation region of a die; and
after contacting the substrate with only the bond initiation region, allowing contact between the substrate and other regions of the die.

19. The method of claim 18, wherein allowing contact between the substrate and other regions of the die comprises transmitting a signal from a controller to the at least one voltage activated cell to control contact between the substrate and other regions of the die.

20. The method of claim 18, wherein contacting the substrate with a bond initiation region of a die comprises transmitting a signal from a controller to the at least one voltage activated cell to control the propagation of a bonding wave between the die and the substrate.
